(19) United States
(12) Patent Application Publication
(10) Pub. No.: US 2026/0231764 A1
(43) Pub. Date: Aug. 6, 2026

(54) HEAT DISSIPATION INTERFACE MEMBER, PREPARATION METHOD THEREFOR, AND SEMICONDUCTOR PACKAGE COMPRISING SAME

(71) Applicant: AMOGREENTECH CO., LTD., Gimpo-si, Gyeonggi-do (KR)

(72) Inventors: In-Yong SEO, Gimpo-si, Gyeonggi-do (KR); Geunyoung JANG, Gimpo-si, Gyeonggi-do (KR); Seayoung LIM, Gimpo-si, Gyeonggi-do (KR); Hyo-Jung LEE, Gimpo-si, Gyeonggi-do (KR); Gyu Min LEE, Gimpo-si, Gyeonggi-do (KR); Jin Han KIM, Gimpo-si, Gyeonggi-do (KR); Kyung Su KIM, Gimpo-si, Gyeonggi-do (KR)

(73) Assignee: AMOGREENTECH CO., LTD., Gimpo-si, Gyeonggi-do (KR)

(21) Appl. No.: 19/150,988

(22) PCT Filed: Jan. 25, 2024
(86) PCT No.: PCT/KR2024/001190

§ 371 Date: Jul. 25, 2025

(30) Foreign Application Priority Data
Jan. 25, 2023 (KR) 10-2023-0009597

(51) Int. Cl. H10W 40/25; B32B 7/027; B32B 7/12; B32B 25/02; B32B 25/08; B32B 25/14; H10W 40/20

(52) U.S. Cl. CPC H10W 40/257; B32B 7/027; B32B 7/12; B32B 25/02; B32B 25/08; B32B 25/14; H10W 40/233; H10W 40/235; B32B 2250/02; B32B 2250/24; B32B 2264/107; B32B 2307/302; B32B 2307/7376

(57) ABSTRACT

[Summary]

A heat dissipation interface member is provided. The heat dissipation interface member according to an embodiment of the present invention is implemented by comprising: a shape transformation layer which comprises a first matrix including a phase change material and a first ceramic filler dispersed in the first matrix, and an adhesive support layer disposed on at least one surface of the shape transformation layer and comprising a second matrix including a rubber-based compound and a second ceramic filler dispersed in the second matrix. Accordingly, a space between a lower substrate on which elements having non-uniform heights are mounted and an upper substrate can be effectively filled, so that air in the space is easily removed and a heat transfer path between the elements and the upper substrate is formed, thereby implementing a thinned semiconductor package having superior heat dissipation performance.

### CROSS REFERENCE TO THE RELATED APPLICATIONS

This application is the national phase entry of International Application No. PCT/KR2024/001190, filed on Jan. 25, 2024, which is based upon and claims priority to Korean Patent Application No. 10-2023-0009597, filed on Jan. 25, 2023, the entire contents of which are incorporated herein by reference.

### TECHNICAL FIELD

The present invention relates to a heat dissipation interface member, a method for manufacturing the same, and a semiconductor element package including the same, and more specifically, to a heat dissipation interface member that has a structure capable of transforming shape when temperature rises and is capable of filling a step of a substrate, a method for manufacturing the same, and a semiconductor element package including the same.

### BACKGROUND ART

As substrates and element parts in electronic products are integrated and the degree of integration increases, leading to 3D integration, there is a trend in which materials and modules are thinned. As a result, as the density of the elements increases due to the high integration and miniaturization of the elements in a narrow space, heat generation in the semiconductor element is gradually becoming a problem, and the demand for technology to effectively dissipate this heat is also increasing.

In addition, due to the high integration of substrates, it is not uncommon for devices to be provided in the form of substrate packages in which two or more layers of substrates (PCBs) are stacked. In this case, heat dissipation between elements has become an increasingly important issue.

However, unlike the problem of simply interposing a heat dissipation sheet between two flat substrates, when interposing a heat dissipation material between a lower substrate on which an active element, such as a semiconductor chip, is mounted and an upper substrate assembled thereto, as in the case of manufacturing a semiconductor package or stacking a semiconductor package, a number of steps of non-uniform size occur on the surface due to a difference in thickness between various elements mounted on the lower substrate. Therefore, even if a heat dissipation sheet is disposed between the lower substrate and the upper substrate, there is a problem that sufficient heat dissipation performance cannot be achieved because there are elements that do not come into contact with the heat dissipation sheet.

Accordingly, it is necessary to develop a heat dissipation material that can overcome the steps between parts such as elements with non-uniform steps.

### SUMMARY OF THE INVENTION

The present invention has been devised in consideration of the above points, and aims to provide a heat dissipation interface member that can effectively fill non-uniform steps caused by a plurality of heat-generating parts with different heights through an area implemented so that the rigidity and shape transformation level vary depending on the temperature.

In addition, the present invention has another object of providing a manufacturing method capable of manufacturing a heat dissipation interface member having the above-described purpose at a low cost by a simple process.

Furthermore, the present invention has still another object of providing a semiconductor package that can achieve excellent heat dissipation efficiency and a thinned thickness by effectively filling the steps caused by elements with different heights through the heat dissipation interface member according to the present invention.

In order to solve the above-described problem, the present invention provides a heat dissipation interface member comprising: a shape transformation layer which comprises a first matrix comprising a phase change material and a first ceramic filler dispersed in the first matrix and has a compressibility measured by the following measurement method at a temperature in the range of 45 to 46° C. that is 50% to 100% greater than a compressibility measured at a temperature in the range of 33 to 34° C., and an adhesive support layer disposed on at least one surface of the shape transformation layer and comprising a second matrix comprising a rubber-based compound and a second ceramic filler dispersed in the second matrix:

### [Measurement Method]

At 23° C., a shape transformation layer sample with a thickness of T₀ (μm) and a size of 10 mm×10 mm in length and width is attached to a PET film with a size of 20 mm×20 mm in length and width and a thickness of 0.1 mm, and then placed in a compressibility measuring device equipped with a ceramic heater having a size of 10 mm×10 mm so that the ceramic heater and the shape transformation layer are in contact with each other. Then, heat is applied through the ceramic heater to maintain the shape transformation layer at an evaluation temperature. In that state, the load is increased using a jig of 5φ in size to reach a maximum load of 0.05 kgf, the pressure is released, and then the sample is left for 5 minutes. Then, the thickness (T, μm) is measured, and the compressibility (C) is calculated according to the following mathematical equation 1:

$$C ( \% ) = \frac{{T}_{o} - T}{{T}_{o}} \times 100 \qquad [ Mathematical Equation 1 ]$$

According to an embodiment of the present invention, the shape transformation layer may have a compressibility of 10% to 30% at 33 to 34° C.

In addition, the phase change material may include at least one selected from a paraffin-based compound and a polyglycol-based compound.

In addition, the first matrix may further include a rubber-based compound, the phase change material and the rubber-based compound may each independently be included in an amount of 5 to 20% by weight in the shape transformation layer, and the phase change material and the rubber-based compound may be included at a weight ratio of 1:1.0 to 1.5.

Additionally, the thickness of the heat dissipation interface member may be 50 μm to 500 μm.

In addition, it may have a three-layer structure in which adhesive support layers are disposed on both surfaces of the shape transformation layer.

In addition, the heat dissipation interface member may have a total thickness of 50 μm to 500 μm, and the shape transformation layer may have a thickness of 80% to 99% of the total thickness.

Additionally, the heat dissipation interface member may have a horizontal insulation resistance of 1×10¹²Ω or more.

In addition, the present invention provides a method for manufacturing a heat dissipation interface member, the method comprising the steps of: (1) preparing a shape transformation layer by processing a first solution comprising a first matrix-forming component comprising a phase change material and a first ceramic filler, (2) preparing an adhesive support layer by processing a second solution including a second matrix-forming component comprising a rubber-based compound and a second ceramic filler, and (3) laminating the adhesive support layer on at least one surface of the shape transformation layer, wherein the shape transformation layer is formed such that a compressibility according to the following measurement method at a temperature in the range of 45 to 46° C. is 50% to 100% greater than a compressibility at a temperature in the range of 33 to 34° C.

### [Measurement Method]

At 23° C., a shape transformation layer sample with a thickness of T₀ (μm) and a size of 10 mm×10 mm in length and width is attached to a PET film with a size of 20 mm×20 mm in length and width and a thickness of 0.1 mm, and then placed in a compressibility measuring device equipped with a ceramic heater having a size of 10 mm×10 mm so that the ceramic heater and the shape transformation layer are in contact with each other. Then, heat is applied through the ceramic heater to maintain the shape transformation layer at an evaluation temperature. In that state, the load is increased using a jig of 5φ in size to reach a maximum load of 0.05 kgf, the pressure is released, and then the sample is left for 5 minutes. Then, the thickness (T, μm) is measured, and the compressibility (C) is calculated according to the following mathematical equation 1:

$$C ( \% ) = \frac{{T}_{o} - T}{{T}_{o}} \times 100 \qquad [ Mathematical Equation 1 ]$$

According to an embodiment of the present invention, step (1) may include a process of drying and then cooling the processed first solution.

In addition, the second solution further includes a phase change material, and step (2) may include a process of drying and then cooling the processed second solution.

In addition, the present invention provides a semiconductor package in which the heat dissipation interface member according to the present invention is interposed between a lower substrate on which a number of elements including an active element are mounted and an upper substrate, and is packaged, wherein the heat dissipation interface member is disposed in a space between the lower substrate on which a plurality of elements are mounted and the upper substrate, and the shape transformation layer in the heat dissipation interface member is shape-transformed to cover at least a portion of an upper surface and a side surface of each of the plurality of elements.

According to an embodiment of the present invention, the shape transformation layer may be further shape-transformed to cover at least a portion of the remaining surface of the upper surface of the lower substrate on which an element is not mounted.

In addition, in the reflow process of assembling the lower substrate and the upper substrate, the shape transformation layer in the heat dissipation interface member is shape-transformed to correspond to the shape of the upper surface of the lower substrate on which the element is mounted, so as to cover the upper surface, and then each of the shape-transformed shape transformation layer and the adhesive support layer may be carbonized to form a carbonized body including a first portion in which a first ceramic filler is dispersed and a second portion in which a second ceramic filler is dispersed.

The heat dissipation interface member according to the present invention effectively fills in non-uniform steps caused by a plurality of heat-generating parts with different heights through an area implemented so that the rigidity and shape transformation level vary depending on the temperature, and maintains the rigidity after filling, thereby advantageously maintains the heat dissipation effect continuously. In addition, since it can be implemented through a simple mixing and stacking process, it is advantageous to reduce manufacturing time and cost.

Furthermore, the heat dissipation interface member according to an embodiment of the present invention can effectively fill steps formed by chips on substrate surfaces between a plurality of substrates to which thinned semiconductor chips are soldered, thereby effectively removing an air layer between the substrates while thinning the thickness of the semiconductor package itself, and thus realizing a thin semiconductor package with excellent heat dissipation performance.

### BRIEF DESCRIPTION OF THE DRAWINGS

FIG. 1 is a schematic cross-sectional view of a heat dissipation interface member according to an embodiment of the present invention;

FIG. 2 is a diagram schematically showing a principle of filling a step between two substrates by shape transformation when manufacturing a semiconductor package using a heat dissipation interface member according to an embodiment of the present invention;

FIG. 3 is a diagram schematically showing a manufacturing process of a heat dissipation interface member according to an embodiment of the present invention; and

FIG. 4 is a photograph of a measuring device for measuring a compressibility of a heat dissipation interface member according to a preferred embodiment of the present invention.

### DETAILED DESCRIPTION

Hereinafter, with reference to the accompanying drawings, embodiments of the present invention will be described in detail so as to be easily implemented by one of ordinary skill in the art to which the present invention pertains. The present invention may be embodied in a variety of forms and is not limited to the embodiments described herein. In order to clearly describe the present invention in the drawing, parts irrelevant to the description are omitted from the drawings; and throughout the specification, same or similar components are referred to as like reference numerals.

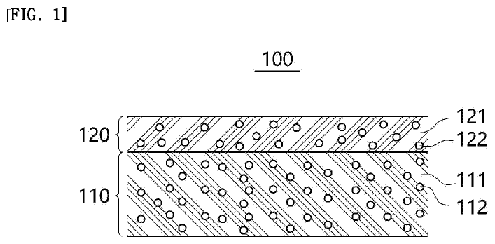

Referring to FIG. 1, a heat dissipation interface member 100 according to an embodiment of the present invention comprises a shape transformation layer 110 and an adhesive support layer 120.

The shape transformation layer 110 is a layer applied to be in contact with a surface where a heat source is located or where there is a step on a heat dissipation path, and has inherent characteristics of changing properties, shape, rigidity, and compression characteristics depending on the temperature, and thus, can easily fill a step even when applied to a plurality of non-uniform step surfaces.

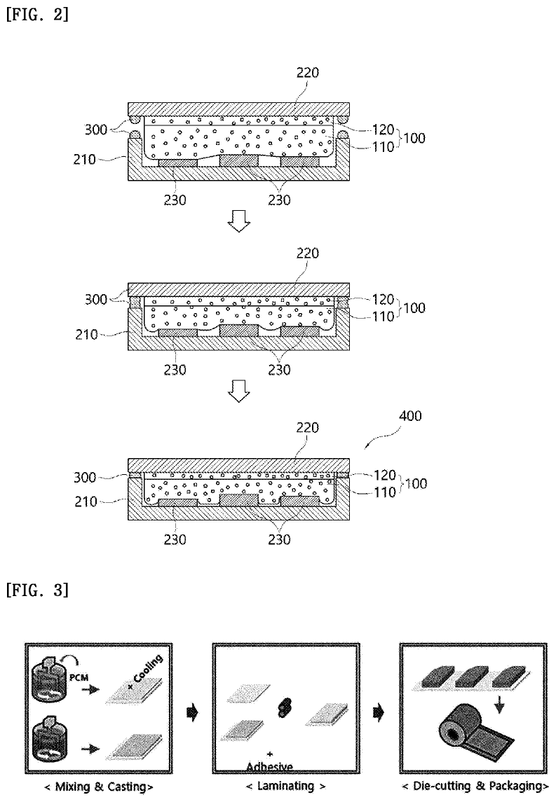

Specifically, the shape transformation layer 110 has a compressibility characteristic according to the following measurement method measured at a temperature in the range of 45 to 46° C. that is 50% to 100%, preferably 60 to 100%, greater than the compressibility measured at a temperature in the range of 33 to 34° C., thereby improving the problem of not being able to sufficiently fill the step of the application surface due to the rigidity of the conventional heat dissipation interface member. Further, since phase change and shape transformation can occur more significantly at a temperature higher than 45 to 46° C., even when the size of the step increases or the width of a concave groove formed by the step (for example, a groove formed by adjacent elements 230 and a lower substrate 210 in FIG. 2) narrows, the phase change and/or the shape transformation can be induced to a degree that the step or the concave groove can be sufficiently filled. Accordingly, the size of an air cap that may exist between elements that respectively contact both surfaces of the heat dissipation interface member 100 can be minimized or eliminated, so that heat dissipation performance can be maximized. Meanwhile, as can be seen from the following measurement method, the compressibility in the present invention is not a compressibility measured in a compressed state by applying a load, but a compressibility calculated based on a thickness (T) measured after creating a compressed state, then releasing the pressure to eliminate the offset of shape transformation characteristics due to elastic recovery force, and then leaving it in the air state for 5 minutes and a thickness before compression (T₀). Accordingly, the compressibility in the present invention is a parameter that measures the degree of shape transformation that is close to or corresponds to permanent transformation.

### [Measurement Method]

At 23° C., a shape transformation layer sample with a thickness of T₀ (μm) and a size of 10 mm×10 mm in length and width is attached to a PET film with a size of 20 mm×20 mm in length and width and a thickness of 0.1 mm, and then placed in a compressibility measuring device equipped with a ceramic heater having a size of 10 mm×10 mm so that the ceramic heater and the shape transformation layer are in contact with each other. Then, heat is applied through the ceramic heater to maintain the shape transformation layer at an evaluation temperature. In that state, the load is increased using a jig of 5φ in size to reach a maximum load of 0.05 kgf, the pressure is released, and then the sample is left for 5 minutes. Then, the thickness (T, μm) is measured, and the compressibility (C) is calculated according to the following mathematical equation 1:

$$C ( \% ) = \frac{{T}_{o} - T}{{T}_{o}} \times 100 \qquad [ Mathematical Equation 1 ]$$

The shape transformation layer 110 includes a first matrix 111 and a first ceramic filler 112 dispersed in the first matrix 111.

The first matrix 111 includes a phase change material to achieve the thermal characteristics of the shape transformation layer 110 described above. The phase change material (PCM) is a material whose phase changes at a specific temperature, and performs functions such as rearrangement of heat transfer particles through shape transformation in the heat dissipation interface member 100, step filling, and removal of an air layer in the step.

In addition, the shape transformation layer 110 has a compressibility of 10 to 30% at 33 to 34° C., or in other words, a compressibility of 10 to 30%, which is a shape transformation level, compared to room temperature, for example, 23° C., and regains rigidity when the shape is transformed by heat and then cooled to room temperature, thereby being advantageous in continuously maintaining effective adhesion and an adhesive form with the application surface to which the shape transformation layer 110 is applied. When the compressibility exceeds 30%, the shape can still be transformed even when cooled, making it difficult to have sufficient rigidity, and as a result, there is a risk that the shape of the layer may collapse, or the layer may be partially or completely lifted from the application surface or may be attached away from the targeted location. In addition, when the compressibility is less than 10%, the temperature that can induce a phase change, that is, cause shape transformation, may be greatly increased, or it may be difficult for shape transformation to occur at a sufficient level, which may be disadvantageous in filling the intended step or removing the air cap.

In a preferred embodiment of the present invention, the phase change material may be at least one selected from a paraffin-based phase change material, an inorganic hydrate, a fatty acid, and a polyglycol-based phase change material. However, it is not limited thereto, and any known phase change material that allows the shape transformation layer 110 to have the above-described thermal characteristics may be used without limitation.

Meanwhile, the phase change temperature of the phase change material generally refers to a melting point. However, the melting point of the phase change material may be adjusted by adding a certain additive. For example, the melting point of the phase change material may preferably be in the range of 30 to 150° C., and more preferably in the range of 40 to 70° C. When the melting point of the phase change material is too high, the temperature required to induce shape transformation may become high, causing heat damage to the application surface or making it difficult to expect heat transfer due to phase change. When the melting point is too low, the rigidity is easily lost at a temperature close to room temperature, which may result in reduced storage stability or reduced processability in application to the application surface. Therefore, it is appropriate to have a melting point in the above range. In addition, as the phase change material, a combination or mixture of two or more materials having different melting points may also be used.

In addition, the first matrix 111 may further include a rubber-based compound in addition to the phase change material, and thus, it may be advantageous for the first matrix 111 to maintain a predetermined shape and rigidity even after the phase change material is melted and vaporized by the applied heat.

The rubber-based compound may be a known rubber-based compound, and for example, may be at least one rubber-based compound selected from the group consisting of isoprene rubber (IR), butadiene rubber (BR), styrene-butadiene rubber (SBR), ethylene propylene diene monomer (EPDM) rubber, acrylic rubber, nitrile-butadiene rubber (NBR), and silicone rubber, and preferably may include styrene-butadiene rubber (SBR), which have advantages of excellent solubility in a solvent, low production cost, increased range of crosslinking agent selection, low density, and excellent interfacial properties with a first ceramic filler 112 described below, compared to other types of rubber-based compounds.

In addition, the rubber-based compound may have a weight average molecular weight of 650,000 to 125, which may be advantageous in improving the content of the first ceramic filler. When the weight average molecular weight of the rubber-based compound is too large, it may be difficult to increase the content of the first ceramic filler, and conversely, when it is too small, it may be advantageous to increase the content of the first ceramic filler, but may be disadvantageous in terms of thermal conductivity.

In addition, the phase change material and the rubber-based compound in the first matrix 111 are each independently included in an amount of 5 to 20 wt % based on the total weight of the shape transformation layer 110, and the phase change material and the rubber-based compound may be included in a weight ratio of 1:1.0 to 1.5 in the first matrix 111, which allows the shape transformation layer 110 to collapse to an appropriate level according to the increased temperature, so that the step of the application surface can be easily filled, and is advantageous in maintaining sufficient rigidity, shape retention, and adhesion at room temperature. In addition, in the case of being applied to a semiconductor package, when a reflow process is performed at a temperature of 200° C. or higher, or for example, 250° C. or higher, it may be advantageous for the first ceramic filler 112 to maintain a single layer shape intact without breaking through the carbonized rubber-based compound remaining in the shape transformation layer 110 region while the phase change material is vaporized and removed.

Meanwhile, when the phase change material in the shape transformation layer 110 is contained in less than 5 wt %, the shape transformation effect due to the applied heat is small, so it may not be sufficient to fill the step of the application surface or remove the air layer. When it exceeds 20 wt %, the shape transformation may be excessive due to the misalignment of the first ceramic filler particles and/or high flowability, and it may flow into an unintended area and cause contamination.

Additionally, the first matrix 111 may further include a curing agent for curing the rubber-based compound contained therein. The curing agent may be a known curing agent in consideration of a specific type of the rubber-based compound selected, and thus, is not particularly limited in the present invention. For example, the curing agent may include at least one of an acid anhydride-based curing agent, an amine-based curing agent, and an isocyanate-based curing agent. Additionally, the content of the curing agent may be 0.5 to 5 parts by weight per 100 parts by weight of the rubber-based compound, but is not limited thereto.

Additionally, the first matrix 111 may further include an acrylic compound to increase compatibility between the rubber-based compound and the phase change material. As the acrylic compound, any known acrylic compound used as an acrylic adhesive may be used without limitation, and the present invention is not particularly limited thereto. For example, the acrylic compound may be contained in an amount of 10 to 50 parts by weight per 100 parts by weight of the rubber-based compound, which may be advantageous to achieve the object of the present invention.

Next, the first ceramic filler 112 is a component that exhibits both heat dissipation and insulation properties, and any particle-shaped component made of a known ceramic component may be used without limitation. The first ceramic filler 112 may be formed of at least one material of, for example, alumina, silicon carbide, magnesium oxide, titanium dioxide, silicon dioxide, yttria, zirconia, aluminum nitride, silicon nitride, boron nitride, silica, zinc oxide, barium titanate, strontium titanate, beryllium oxide, single crystal silicon, and manganese oxide. In addition, the first ceramic filler 112 may have an average particle diameter of 1 to 100 μm, for example, 1 to 50 μm, or 5 to 50 μm, which may be advantageous in increasing dispersibility and achieving the purpose of the present invention.

Additionally, the first ceramic filler 112 may be included in an amount of, for example, 60 to 90 wt % in the shape transformation layer 110. When the first ceramic filler is contained in an amount of less than 60 wt %, the heat dissipation characteristics may deteriorate, and when it exceeds 90 wt %, the shape retention ability is reduced when manufactured and used, and since the content of the rubber-based compound and the phase change material is relatively reduced, it may be difficult to obtain the shape transformation characteristics at the desired level, it may be difficult to sufficiently fill the steps, and it may be difficult for the shape transformation layer region to maintain a predetermined shape after the reflow process.

Next, the adhesive support layer 120 will be described.

The adhesive support layer 120 can perform a support function that physically supports the shape transformation layer 110 described above, an attachment function that allows the heat dissipation interface member 100 to be fixed to another application surface disposed to face the application surface that the shape transformation layer 110 comes into contact with, and a heat dissipation function that transfers heat transferred from the shape transformation layer 110 to the other application surface, etc., through the second ceramic filler 122 dispersed therein.

The adhesive support layer 120 may be disposed on any one surface of the shape transformation layer 110 described above, or on both surfaces of the shape transformation layer 110.

In addition, the adhesive support layer 120 includes a second matrix 121 and a second ceramic filler 122 dispersed in the second matrix 121.

The second matrix 121 includes a rubber-based compound and may further include a curing agent capable of curing the rubber-based compound. The rubber-based compound may be a known rubber-based compound, and for example, may be at least one rubber-based compound selected from the group consisting of isoprene rubber (IR), butadiene rubber (BR), styrene-butadiene rubber (SBR), ethylene propylene diene monomer (EPDM) rubber, acrylic rubber, nitrile-butadiene rubber (NBR), and silicone rubber. Preferably, it may include styrene-butadiene rubber (SBR), which may be advantageous in exhibiting adhesive properties while increasing adhesion when the heat dissipation interface member 100 is interposed between two different members.

In addition, as the curing agent that may be added, any known component used for curing a rubber-based compound may be used without limitation, and a specific description of the curing agent is omitted because it is the same as the description of the curing agent described in the first matrix 111 described above.

Meanwhile, it is preferable that the rubber-based compound further contained in the first matrix 111 described above is the same type as the rubber-based compound in the second matrix 121, thereby improving the bonding force between the first matrix 111 and the second matrix 121, which may be advantageous in securing shape stability and rigidity at room temperature.

Next, the second ceramic filler 122 dispersed in the second matrix 121 is a component that exhibits both heat dissipation and insulation properties, and any particle-shaped component made of a known ceramic component may be used without limitation. The second ceramic filler 122 may be formed of at least one material of, for example, alumina, silicon carbide, magnesium oxide, titanium dioxide, silicon dioxide, yttria, zirconia, aluminum nitride, silicon nitride, boron nitride, silica, zinc oxide, barium titanate, strontium titanate, beryllium oxide, single crystal silicon, and manganese oxide. In addition, the second ceramic filler 122 may have an average particle diameter of 1 to 100 μm, for example, 1 to 50 μm, or 5 to 50 μm, which may be advantageous in increasing dispersibility and achieving the purpose of the present invention.

Additionally, the second ceramic filler 122 may be included in an amount of, for example, 80 to 95% by weight in the adhesive support layer 120. When the content of the second ceramic filler in the adhesive support layer 120 is less than 80 wt %, there is a risk that the heat dissipation characteristics may deteriorate, and when it exceeds 95 wt %, there is a risk that the adhesive characteristics and support characteristics may deteriorate.

In a preferred embodiment of the present invention, the heat dissipation interface member 100 may have a thickness of 50 μm to 500 μm, more preferably 70 μm to 300 μm, even more preferably 80 μm to 250 μm, and even more preferably 90 μm to 180 μm.

Additionally, the shape transformation layer 110 described above may have a thickness of 80% to 99% of the total thickness of the heat dissipation interface member 100. When the thickness of the shape transformation layer 110 is less than 80% of the total thickness of the heat dissipation interface member 100, the thermal conductivity may decrease, and it may be difficult to achieve sufficient thinning when the heat dissipation interface member 100 is interposed between two application surfaces. In addition, when the thickness exceeds 99% of the total thickness, the thickness of the adhesive support layer becomes relatively thin, which makes it difficult to form the adhesive support layer itself with a uniform thickness, or the adhesiveness may be low, resulting in insufficient adhesion.

In addition, in an embodiment of the present invention, the heat dissipation interface member 100 may have a horizontal insulation resistance value of 1×10¹²Ω or more, and as another example, 1×10¹⁷Ω or less. The imparted insulating properties can prevent an electric leakage between various elements placed on the application surface. When the horizontal insulation resistance value is less than 1×10¹²Ω, the risk of electric leakage increases, and the current due to the electric leakage generates additional heat, which may run counter to the function of the heat dissipation interface member. Meanwhile, an insulation resistance value exceeding 1×10¹⁷Ω practically means that the insulation resistance is close to infinity, and in order to implement this, a large increase in the overall thickness of the heat dissipation interface member and/or a reduction in the phase change material must inevitably be accompanied, which is contrary to thinning and may significantly reduce the step filling property due to a decrease in shape transformation characteristics, which may run counter to the purpose of the present invention.

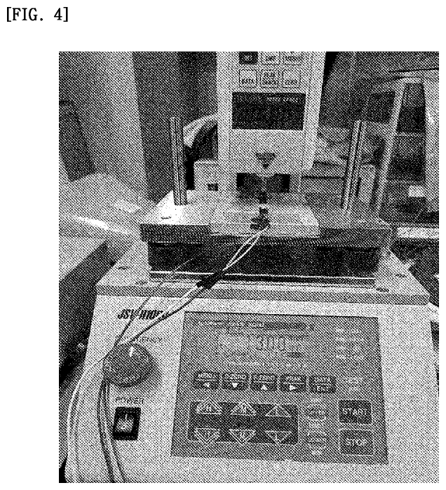

Referring to FIG. 3, the heat dissipation interface member 100 according to an embodiment of the present invention described above may be manufactured by including the steps of: (1) preparing a shape transformation layer 110 by processing a first solution including a first matrix-forming component including a phase change material and a first ceramic filler, (2) preparing an adhesive support layer 120 by processing a second solution including a second matrix-forming component including a rubber-based compound and a second ceramic filler, and (3) laminating the adhesive support layer on at least one surface of the shape transformation layer.

In steps (1) and (2), the shape transformation layer 110 and the adhesive support layer 120 are prepared using the first solution and the second solution, respectively, and may be prepared by, for example, processing the first solution and the second solution on a substrate such as a release member, respectively.

Specifically, the first solution includes a first matrix-forming component including a phase change material and a first ceramic filler, and as described above, the first matrix-forming component may further include a rubber-based compound, an acrylic compound, a curing agent, etc.

In addition, the second solution includes a second matrix-forming component including a rubber-based compound and a second ceramic filler, and as described above, the second matrix-forming component may further include a phase change material, a curing agent, etc.

Additionally, the first solution and the second solution may further include a solvent for dispersing or dissolving the included materials. The solvent may be a non-polar solvent such as toluene, xylene, or methyl ethyl ketone. For example, the content of the solvent may be 100 to 1,000 parts by weight based on 100 parts by weight of the first or second matrix-forming component, and the content may be adjusted to implement an appropriate viscosity in consideration of the formation method of each layer. However, it should be noted that the solvent is not necessarily included, and for example, in the case of the first solution, it may be implemented in a solution phase by increasing the temperature to melt the phase change material contained therein.

In addition, the first solution and the second solution may be respectively processed on the substrate, wherein the treatment may be a known coating method, and examples thereof may include, but are not limited to, knife coating, blade coating, roll coating, cast coating, spray coating, air knife coating, etc.

In addition, the first solution and the second solution, which are processed to have a predetermined thickness on the substrate, may be dried at 60 to 120° C. for 2 to 10 minutes, but this is not limited thereto and may be appropriately changed in consideration of the type and viscosity of the solvent used.

In addition, the first solution processed on the substrate may be implemented as the shape transformation layer 110 through a cooling process after drying, which may be advantageous in securing the rigidity of the dried formation transformation layer 110 and maintaining the desired shape and thickness. The cooling process may be, for example, cooling to room temperature or 10° C. or lower, and the cooling time may be 30 seconds or less, but is not limited thereto. Meanwhile, it should be noted that even in the case where the second solution further contains a phase change material depending on the purpose, the processed second solution may further undergo the above-described cooling process after drying.

The shape transformation layer 110 and the adhesive support layer 120 respectively implemented through the above-described steps (1) and (2) may be laminated in contact with each other to be implemented as an integrated heat dissipation interface member 100. The lamination may be performed by a known method, and is not particularly limited in the present invention. In addition, a predetermined pressure may be applied during the lamination, wherein the pressure may be applied using a calendaring or plate press, and the present invention is not particularly limited thereto. Additionally, it is noted that steps (1) and (2) are performed regardless of order.

The heat dissipation interface member 100 according to an embodiment of the present invention described above may be provided in a semiconductor package in which a plurality of elements including an active element are packaged with a lower substrate and an upper substrate.

Specifically, referring to FIG. 2, a lower substrate 210 on which a plurality of elements 230 including an active element are mounted may be combined with an upper substrate 220 to be implemented as a single semiconductor package 400.

In this case, the heat dissipation interface member 100 placed between the lower substrate 210 and the upper substrate 220 is subjected to a reflow process at a high temperature, for example, 200° C., or as another example, 250° C. or higher, to bond the lower substrate 210 and the upper substrate 220, so that the phase change material in the shape transformation layer 110 is phase-transferred into a liquid phase by the applied heat, and the first ceramic filler 112 that is shape-transformed and dispersed by the pressurized upper substrate 220 is rearranged, thereby filling the concave groove formed by the adjacent elements 230 and the lower substrate 210 or the step formed by the elements 230. In addition, the step filling due to the shape transformation layer 110 of the heat dissipation interface member 100 by the bond between the lower substrate 210 and the upper substrate 220 can further improve the heat dissipation characteristics by removing the air cap existing between the two substrates. In the filling by the shape transformation layer 110 as described above, the shape of the shape transformation layer 110 may be transformed to cover at least a portion of the upper surface and side surfaces of each of the plurality of elements 230, and preferably, the shortest distance between the bottom surface of the transformed shape transformation layer 110 and the lower substrate 210 may be ⅓ or less compared to the thickness of the semiconductor chip with the lowest height. More preferably, the shape may be transformed to cover a portion of the side surface of each of the elements 230 and the upper surface of the lower substrate 210 connected thereto, and even more preferably, the shape may be transformed to cover all of the side surface of each of the elements 230 and the upper surface of the lower substrate 210 connected thereto, whereby the air gap existing between the shape transformation layer 110 and the lower substrate 210 can be removed, thereby further improving the heat dissipation characteristics.

Meanwhile, when the heat applied during the reflow process is transferred to the shape transformation layer 110 and the shape transformation layer 110 is heated to a temperature higher than the melting point of the phase change material due to the transferred heat, the phase change material is phase-transferred into a liquid phase as described above, and the shape of the shape transformation layer 110 is transformed to fill the step as described above. However, the first matrix 111 may be cured simultaneously due to the greater heat transferred during the reflow process. In addition, when the heat transferred to the shape transformation layer 110 is eventually equilibrated at a temperature of 200° C. or higher, or in another example, 250° C. or higher, at which the reflow process is performed, the phase change material contained therein is vaporized, and since the phase change material is no longer included in the first matrix, shape transformation no longer occurs, and the remaining rubber-based compound or other material forming the first matrix 111 is in a carbonized state and forms one body with the first ceramic filler 112, so that the elements 230 can be firmly bonded to the lower substrate 210 on which they are mounted. In addition, in the adhesive support layer 120, as in the shape transformation layer 110, the rubber-based compound or other material forming the second matrix can be carbonized to form one body with the second ceramic filler 122.

Ultimately, in the reflow process of assembling the lower substrate 210 and the upper substrate 220, the shape transformation layer 110 in the heat dissipation interface member 100 is shape-transformed to correspond to the shape of the upper surface of the lower substrate 210 on which the element 230 is mounted, so as to cover the upper surface, and then, the shape-transformed shape transformation layer 110 and the adhesive support layer 120 may be carbonized to form a carbonized body including a first portion in which the first ceramic filler 112 is dispersed and a second portion in which the second ceramic filler 122 is dispersed, thereby implementing a semiconductor package 400 with excellent bonding force and improved internal interface characteristics in the space between the upper substrate 220 and the lower substrate 210 on which the elements 230 are mounted.

In addition, the carbonized body including the first portion in which the first ceramic filler 112 is dispersed and the second portion in which the second ceramic filler 122 is dispersed, which are ultimately provided in the semiconductor package 400, has excellent insulation properties as the horizontal and vertical insulation resistances independently achieve 1×10¹² or more.

Hereinafter, the present invention will be described in more detail by way of the following examples, but it should be understood that the examples are not intended to limit the scope of the present invention, but to aid understanding of the present invention.

### Example 1

In order to prepare a shape transformation layer, a paraffin-based phase change material having a liquid phase transition temperature of 40° C. and SBR (200° C. MFR of 5.3 g/min, weight average molecular weight of 780,000), a rubber-based compound, as first matrix-forming components were mixed in a weight ratio of 1:1.3, and 1 part by weight of a peroxide-based curing agent per 100 parts by weight of the rubber-based compound was mixed. Then, the first matrix-forming component and alumina (average particle diameter of about 20 μm), a first ceramic filler, are mixed in toluene as a solvent so that they account for 16% by weight and 84% by weight in the shape transformation layer, respectively, and stirred to prepare a first solution.

In addition, in order to prepare an adhesive support layer, 1 part by weight of a peroxide-based curing agent was mixed with 100 parts by weight of SBR (200° C. MFR of 5.3 g/min, weight average molecular weight of 780,000), a rubber-based compound, as a second matrix-forming component, and then mixed in toluene as a solvent so that the second matrix-forming component accounted for 10 wt % and alumina (average particle diameter of about 20 μm), a second ceramic filler, accounted for 90 wt % in the adhesive support layer, and then stirred to prepare a second solution.

The prepared first solution was processed on a substrate using a comma coater to a predetermined thickness, and then dried at 100° C. for 5 minutes to implement a shape transformation layer having a thickness of about 220 μm, which was then rapidly cooled to 10° C. using a cooling device. In addition, the second solution was processed on a substrate using a comma coater to a predetermined thickness, and then dried at 100° C. for 5 minutes to implement an adhesive support layer having a thickness of about 30 μm. Thereafter, the prepared shape transformation layer and the adhesive support layer were laminated to manufacture a heat dissipation interface member as shown in Table 1.

### Comparative Example 1

A heat dissipation interface member as shown in Table 1 was manufactured by performing the same process as in Example 1, except for changing the content of the phase change material in the first matrix-forming component.

### Comparative Example 2

A heat dissipation interface member as shown in Table 1 was manufactured by performing the same process as in Example 1, except for excluding the phase change material in the first matrix-forming component.

### Experimental Example

The following properties were evaluated for the heat dissipation interface members of Example 1 and Comparative Examples 1 to 2, and were shown in Table 1.

### 1. Evaluation of Compression Characteristics According to Temperature of Shape Transformation Layer

Samples were prepared by separating the shape transformation layers having a thickness of 120 μm (T₀) at 23° C. provided in the heat dissipation interface members of Example 1 and Comparative Example 1, and then cutting them to have a width and length of 10 mm×10 mm, respectively.

The prepared sample was attached to a PET film with a size of 20 mm×20 mm in length and width and a thickness of 0.1 mm, and then placed in a compressibility measuring device equipped with a ceramic heater having a size of 10 mm×10 mm as shown in FIG. 4 so that the ceramic heater and the shape transformation layer were in contact with each other. Then, heat was applied through the ceramic heater to maintain the temperature of the shape transformation layer at 33.5° C. (T₁). In that state, the load was increased using a jig of 5φ in size to reach a maximum load of 0.05 kgf, the pressure was released, the sample was left in the air state for 5 minutes, and then the thickness (T) was measured.

In addition, in a state in which the temperature of the shape transformation layer was maintained at 45.4° C. (T₂) in the same way, the load was increased using a jig of 5φ in size to reach a maximum load of 0.05 kgf, the pressure was released, the sample was left in the air state for 5 minutes, and then the thickness (T) was measured.

The compressibility (C) was calculated according to Mathematical Equation 1 below by using the thickness (T) measured at two different temperatures (T₁, T₂), respectively, and the thickness before evaluation (T₀).

$$C ( \% ) = \frac{{T}_{o} - T}{{T}_{o}} \times 100 \qquad [ Mathematical Equation 1 ]$$

In addition, an increase ratio (%) of the compressibility @T₂ compared to the compressibility @T₁ was calculated using Mathematical Equation 2 below:

$$Increase ratio ( \% ) of compressibility @ {T}_{2} compared to compressibilty @ {T}_{1} = [ ( {C}_{T 2} - {C}_{T 1} ) / {C}_{T 1} ] \times 100 \qquad [ Mathematical Equation 2 ]$$

wherein C_{T1} and C_{T2} represent the compressibility @T₁ and the compressibility @T₂, respectively.

### 2. Step Filling Property

In order to examine the step filling characteristics through the shape transformation layer, the shape transformation layer was placed in contact with the lower substrate for evaluation, and then solder cream was interposed between the upper and lower substrates to perform a reflow process at a temperature of 260° C., thereby performing a simulated semiconductor packaging process as shown in FIG. 2. Thereafter, the cross-section of the implemented semiconductor packaging was cut, and then the shortest distance between the bottom surface of the carbonized shape transformation layer that filled the space between the two mounted semiconductor chips and the lower substrate was measured using SEM photography.

In this case, as the substrate for evaluation, a lower substrate on which semiconductor chips with heights of 35 μm and 50 μm were mounted with a spacing of 40 μm was prepared.

### 3. Insulation Resistance Measurement

The horizontal insulation resistance of both surfaces was measured using a withstand voltage measuring device (IR 4051), and the minimum value was shown in the table.

TABLE 1

| | | | Compar- | Compar- |
|---|---|---|---|---|
| | | | ative | ative |
| | | Exam- | Exam- | Exam- |
| | | ple 1 | ple 1 | ple 2 |
| Shape transformation layer | | 220 | 220 | 220 |
| thickness (μm) | | | | |
| Presence or absence of phase | | Included | Included | Not |
| change material in shape | | | | included |
| transformation layer | | | | |
| Shape | Compressibility | 18.1 | 18.2 | 0 |
| transformation | (@T₁, 33.5° C.) | | | |
| layer | Compressibility | 27.6 | 26.1 | 0 |
| Compressibility | (@T₂, 45.4° C.) | | | |
| (C, %) | Increase ratio (%) | 52.5 | 43.4 | 0 |
| | of compressibility | | | |
| | @T₂ compared to | | | |
| | compressibility | | | |
| | @T₁ | | | |

| | | | |
|---|---|---|---|
| Step filling property (distance | 9.1 μm | 22.4 μm | 28.5 μm |
| between bottom surface of | | | |
| carbonized shape transformation | | | |
| layer and lower substrate) | | | |
| Horizontal insulation resistance (Ω) | >1 × 10¹² | >1 × 10¹² | >1 × 10¹² |

As can be seen from Table 1, in the case of Example 1, it can be seen that the increase ratio (%) of the compressibility @T₂ compared to the compressibility @T₁ is 52.5%, the phase change material is included in the shape transformation layer, and the step filling property is greatly increased compared to Comparative Example 1 in which the increase ratio (%) of the compressibility @T₂ compared to the compressibility @T₁ is 43.4%.

Meanwhile, in the case of Comparative Example 2, which does not contain the phase change material in the shape transformation layer, it can be seen that the step filling property is small when considering the height of the chip.

Although an embodiment of the present invention have been described above, the spirit of the present invention is not limited to the embodiment presented in the subject specification; and those skilled in the art who understands the spirit of the present invention will be able to easily suggest other embodiments through addition, changes, elimination, and the like of elements without departing from the scope of the same spirit, and such other embodiments will also fall within the scope of the present invention.

1. A heat dissipation interface member comprising:
a shape transformation layer which comprises a first matrix comprising a phase change material and a first ceramic filler dispersed in the first matrix and has a compressibility according to the following measurement method at a temperature in the range of 45 to 46° C. that is 50% to 100% greater than a compressibility at a temperature in the range of 33 to 34° C.; and
an adhesive support layer disposed on at least one surface of the shape transformation layer and comprising a second matrix comprising a rubber-based compound and a second ceramic filler dispersed in the second matrix:
[Measurement Method]
At 23° C., a shape transformation layer sample with a thickness of T₀ (μm) and a size of 10 mm×10 mm in length and width is attached to a PET film with a size of 20 mm×20 mm in length and width and a thickness of 0.1 mm, and then placed in a compressibility measuring device equipped with a ceramic heater having a size of 10 mm×10 mm so that the ceramic heater and the shape transformation layer are in contact with each other. Then, heat is applied through the ceramic heater to maintain the shape transformation layer at an evaluation temperature. In that state, the load is increased using a jig of 5φ in size to reach a maximum load of 0.05 kgf, the pressure is released, and then the sample is left for 5 minutes. Then, the thickness (T, μm) is measured, and the compressibility (C) is calculated according to the following mathematical equation 1:
$$C ( \% ) = \frac{{T}_{o} - T}{{T}_{o}} \times 100 \qquad [ Mathematical Equation 1 ]$$

2. The heat dissipation interface member according to claim 1, wherein the shape transformation layer has a compressibility of 10% to 30% at 33 to 34° C.

3. The heat dissipation interface member according to claim 1, wherein the phase change material includes at least one selected from a paraffin-based compound and a polyglycol-based compound.

4. The heat dissipation interface member according to claim 1, wherein the first matrix further comprises a rubber-based compound,
the phase change material and the rubber-based compound is each independently included in an amount of 5 to 20% by weight in the shape transformation layer, and
the phase change material and the rubber-based compound are included at a weight ratio of 1:1.0 to 1.5.

5. The heat dissipation interface member according to claim 1, wherein the thickness of the heat dissipation interface member is 50 μm to 500 μm.

6. The heat dissipation interface member according to claim 1, wherein the adhesive support layer are disposed on both surfaces of the shape transformation layer.

7. The heat dissipation interface member according to claim 1, wherein the heat dissipation interface member has a total thickness of 50 μm to 500 μm, and the shape transformation layer has a thickness of 80% to 99% of the total thickness.

8. The heat dissipation interface member according to claim 1, wherein the heat dissipation interface member has a horizontal insulation resistance of 1×10¹²Ω or more.

9. A method for manufacturing a heat dissipation interface member, the method comprising the steps of:
(1) preparing a shape transformation layer by processing a first solution comprising a first matrix-forming component comprising a phase change material and a first ceramic filler;
(2) preparing an adhesive support layer by processing a second solution including a second matrix-forming component including a rubber-based compound and a second ceramic filler; and
(3) laminating the adhesive support layer on at least one surface of the shape transformation layer,
wherein the shape transformation layer is formed such that a compressibility according to the following measurement method at a temperature in the range of 45 to 46° C. is 50% to 100% greater than a compressibility at a temperature in the range of 33 to 34° C.:
[Measurement Method]
At 23° C., a shape transformation layer sample with a thickness of T₀ (μm) and a size of 10 mm×10 mm in length and width is attached to a PET film with a size of 20 mm×20 mm in length and width and a thickness of 0.1 mm, and then placed in a compressibility measuring device equipped with a ceramic heater having a size of 10 mm×10 mm so that the ceramic heater and the shape transformation layer are in contact with each other. Then, heat is applied through the ceramic heater to maintain the shape transformation layer at an evaluation temperature. In that state, the load is increased using a jig of 5φ in size to reach a maximum load of 0.05 kgf, the pressure is released, and then the sample is left for 5 minutes. Then, the thickness (T, μm) is measured, and the compressibility (C) is calculated according to the following mathematical equation 1:
$$C ( \% ) = \frac{{T}_{o} - T}{{T}_{o}} \times 100 \qquad [ Mathematical Equation 1 ]$$

10. The method for manufacturing a heat dissipation interface member according to claim 9, wherein step (1) includes a process of drying and then cooling the processed first solution.

11. The method for manufacturing a heat dissipation interface member according to claim 9, wherein the second solution further includes a phase change material, and
step (2) includes a process of drying and then cooling the processed second solution.

12. A semiconductor package in which the heat dissipation interface member according to claim 1 is interposed between a lower substrate on which a number of elements comprising an active element are mounted and an upper substrate, and is packaged,
wherein the heat dissipation interface member is disposed in a space between the lower substrate on which a plurality of elements are mounted and the upper substrate, and
the shape transformation layer in the heat dissipation interface member is shape-transformed to cover at least a portion of an upper surface and a side surface of each of the plurality of elements.

13. The semiconductor package according to claim 12, wherein the shape transformation layer is further shape-transformed to cover at least a portion of the remaining surface of the upper surface of the lower substrate on which an element is not mounted.

14. The semiconductor package according to claim 12, wherein in the reflow process of assembling the lower substrate and the upper substrate, the shape transformation layer in the heat dissipation interface member is shape-transformed to correspond to the shape of the upper surface of the lower substrate on which the element is mounted, so as to cover the upper surface, and then each of the shape-transformed shape transformation layer and the adhesive support layer is carbonized to form a carbonized body including a first portion in which a first ceramic filler is dispersed and a second portion in which a second ceramic filler is dispersed.
